(19) United States
(12) Patent Application Publication
(10) Pub. No.: US 2004/0031982 A1
(43) Pub. Date: Feb. 19, 2004

(54) Interdigitated integrated circuit capacitor

(76) Inventors: Christopher Andrew Devries, Ottawa (CA); Ralph Dickson Mason, Ottawa (CA)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/639,545

(22) Filed: Aug. 12, 2003

(30) Foreign Application Priority Data
Aug. 12, 2002 (CA) 2,395,900

(51) Int. Cl. H01L 27/108; H01L 29/76; H01L 29/94; H01L 31/119

(52) U.S. Cl. 257/307

(57) ABSTRACT

The invention relates to the field of microelectronics, more particularly to the structure and layout of integrated circuit capacitors. An integrated circuit capacitor is provided comprising: a first conductive component comprising a plurality of digital sub-components; and a second conductive component comprising a plurality of digital sub-components; wherein the digital sub-components of the first and second conductive components are interleaved and parallel, with a narrow uniform distance therebetween; and wherein the orientation of the interleaved digital sub-components is symmetrical about the center of the integrated circuit capacitor. This symmetrical orientation aids in the creation of a capacitor with well-matched top and bottom plates and capacitor pairs that have well-defined ratios. The arrangement serves to minimize the photolithographic variations by averaging the offsets caused by the different lithographic traces.

### BACKGROUND OF THE INVENTION

1. Field of the Invention

The invention relates to the field of microelectronics, more particularly to the structure and layout of integrated circuit capacitors.

2. Description of the Related Prior Art

As will be understood by those skilled in the art, an integrated circuit (IC), sometimes called a chip or microchip is a semiconductor material on which thousands of tiny resistors, capacitors, and transistors are fabricated in a particular configuration to perform a desired electronic function. For example, a chip can function as an amplifier, oscillator, timer, counter, computer memory or microprocessor. A particular chip is categorized as either digital or analogue, depending on its intended application.

The manufacture of a chip involves a variety of steps, one of which is a photolithography. Photolithography is the process of transferring geometric shapes on a mask to the surface of a silicon wafer. The steps involved in the photolithographic process are wafer cleaning; barrier layer formation; photoresist application; soft baking; mask alignment; exposure and development; and hard-baking. Once photolithography has taken place, electrical interconnects through the silicon using one of a variety of etching techniques is performed. When all processing is complete, the resulting wafer is diced using scribing tools into dies or chips. The end product is delicate in nature so is incorporated into some form of packaging.

Several well known packaging techniques have been developed, one of which is a quad flat pack (QFP). As shown in FIG. 1, a QFP package comprises a chip 10, which is protected using an epoxy resin 12. From the chip 10 extend wire bonds 14 (typically gold (Au)) which connect to leads 16 (typically lead/tin (Pb/Sn) plated) which may have silver spot plating at the contact point, as shown at 18. The leads 16 are connected (soldered) to a printed circuit board (not shown). An adhesive or solder 20 is used to adhere the chip to the carrier pad or substrate 22.

As will also be appreciated, two conductors separated by a dielectric or non-conductor exhibit the property called capacitance, because the combination can store an electric charge in an electrostatic field. Within the field of integrated circuits, traditional forms of capacitance include gate capacitance, junction capacitance and metal to metal/polysilicon (poly) (parallel plate) capacitance. Metal to metal capacitors typically comprise two metal layers separated by a dielectric. Alternatively, polysilicon may be substituted for metal. Metal to metal capacitors provide linear operation, a high Q factor, and a small temperature coefficient. These features make metal-to-metal capacitors the preferred type of capacitor for many integrated circuit applications. However, metal-to-metal capacitors have a relatively low capacitance per unit area. Therefore, capacitors of this form often take up large areas on an integrated circuit. Such large capacitors can significantly increase the cost of an integrated circuit.

Several parallel plate capacitor structures have been developed such as those shown in FIGS. 2(a) to 2(d) to minimize the space requirement. For example, as shown in FIG. 2(c), the interdigital electrodes of plate 24 are woven with the interdigital electrodes of plate 26 to provide a dense capacitor structure. FIGS. 3(a) to 3(d) highlight the flux arising from various parallel plate arrangements. In the plate arrangement shown in FIG. 3(a), only vertical flux lines 28 associated with an electrostatic field are present. In the arrangement shown in FIG. 3(b), both vertical flux lines 28 and lateral flux lines 30 are present, due to the proximity of multiple plates at a single level. Lateral flux is important because it increases the overall capacitance. Typical horizontal spacing can be in the range of 0.6 μm, while vertical spacing can be in the range of 0.81 μm. As will be discussed in more detail below, in general, as process size shrinks, the horizontal spacing shrinks more than the vertical spacing. FIG. 3(c) highlights a problem arising when the capacitor structure is located near an undesirable structure such as substrate 32 or any ground or power connection. Undesirable parasitic capacitance occurs because some of the electrostatic field lines terminate on substrate 32 (so called bottom-wall capacitance).

In terms of manufacturing a parallel plate capacitor, traditionally each conductive plate was on a different conductive layer separated by a special thin oxide. Because this requires special processing steps, not used in standard digital circuitry, many designers were forced to use metal interconnection layers, separated by standard dielectrics. Parallel plate capacitors using this method had a much lower density (capacitance per area) and higher parasitic capacitances than the specialized capacitance process.

Recently, due to the shrinking dimensions in deep sub-micron processes, designers have been choosing to use the capacitance created by lateral flux within a single metal layer. See for example U.S. Pat. No. 4,409,608 entitled “Recessed Interdigitated Integrated Circuit” issued on Oct. 11, 1983 to Yoder. Since the minimum spacing between interconnect layers for deep sub-micron processes is becoming much smaller and better controlled than the dielectric thickness, the capacitance density and matching for this type of capacitor is better than a horizontal parallel plate capacitor in the same technology. Other methods such as the method described in U.S. Pat. No. 5,939,766 entitled “High Quality Capacitor for Sub-Micrometer Integrated Circuits” issued Aug. 17, 1999 to Stolmeijer et al have attempted to improve on the capacitance density, but the highest density capacitor is obtained by using interleaved vertical posts or fingers as discussed by Aparcio, R and Hajimiri, A in “Capacity Limits and Matching Properties of Integrated Capacitors”, IEEE Journal of Solid State Circuits, vol. 37 no. 3, March 2002. However, this structure is undesirable because it has high resistive losses and uses two metal interconnect layers for the connection of the fingers.

As discussed above, both plates of the capacitor will experience parasitic capacitances to the ground or power connection of the integrated circuit. For many circuit designs it is desirable to have both plates of the capacitor exactly the same, i.e. with the same parasitic capacitance. Furthermore, many circuit designs rely on the matching of two different capacitors. Many different techniques, such as the use of fractal structures have been constructed to improve the matching of the capacitors. Such techniques are described, for example, in U.S. Pat. No. 6,028,990 entitled “Method and Apparatus for a Lateral Flux Capacitor” issued Feb. 22, 2000 to Shahani et al.

In integrated circuit technology, the photolithography used to create conductive geometries will deviate from the ideal. The amount of deviation varies from one chip to another and within the chip itself. Often, the deviation from the ideal of a geometry is related to the direction of that geometry. For example, a conductor drawn on the x-axis may have a width 10% greater than ideal, while an conductor intended to match, drawn on the y-axis may have a width 10% less. It is desirable to have a capacitor structure that minimizes this variation by averaging the offsets caused by the different lithographic traces.

In light of the problems and deficiencies of present integrated circuit capacitors highlighted above, there is a need for an improved integrated circuit capacitor structure that minimizes this variation by averaging the offsets caused by the different lithographic traces.

### SUMMARY OF THE INVENTION

In order to overcome the deficiencies of the prior art there is provided an integrated circuit capacitor having uniquely configured plates oriented in such a way as to allow good matching between the two plates and from one integrated circuit capacitor to another.

More specifically, the integrated circuit capacitor of the present invention involves the incorporation of a plurality of connected lateral flux capacitors in varying orientation. An integrated circuit capacitor is provided with two conductive plates in a single layer, each plate including a plurality of digital conductors. The plates are disposed across four regions, each region a lateral flux capacitor with the digital conductors oriented at ninety degrees from the adjacent region. In each region, the digital conductors from the two conductive plates are interleaved and parallel to one another, with a narrow uniform distance between their edges. The integrated circuit capacitor can be extended to two or more conductive layers with the flux capacitors on each layer being electrically coupled thereto. This multi-layer integrated circuit capacitor can also be oriented such that the lateral flux capacitor regions from one layer to another are perpendicular to those of the adjacent conducting layer.

In one aspect of the invention there is provided an integrated circuit capacitor comprising: a first conductive component comprising a plurality of digital sub-components; and a second conductive component comprising a plurality of digital sub-components; wherein the digital sub-components of the first and second conductive components are interleaved and parallel, with a narrow uniform distance therebetween; and wherein the orientation of the interleaved digital sub-components is symmetrical about the center of the integrated circuit capacitor.

Preferably, the first and second conductive components of the integrated circuit capacitor are oriented about a common plane, and the conductive components form at least four distinct regions within the common plane, and wherein a selected one of the four distinct regions is symmetrical to the diagonally opposite region and perpendicular to each adjacent region.

More preferably, the integrated circuit capacitor further comprises at least a second plane parallel to the common plane and having third and fourth conductive components disposed therein, wherein the third and fourth conductive components are identically oriented as the first and second conductive components, and wherein the first conductive component is electrically coupled to the third conductive component and the second conductive component is electrically coupled to said fourth conductive component using a plurality of vias.

Even more preferably, the third and fourth conductive components are oriented in a 90° relationship to the first and second conductive components.

The advantage of the present invention is readily apparent. The symmetrical orientation aids in the creation of a capacitor with well-matched top and bottom plates and capacitor pairs that have well defined ratios. The arrangement serves to minimize the photolithographic variations by averaging the offsets caused by the different lithographic traces.

### BRIEF DESCRIPTION OF THE DRAWINGS

A better understanding of the invention will be obtained by considering the detailed description below, with reference to the following drawings in which:

FIG. 1 depicts a typical integrated circuit of the prior art;

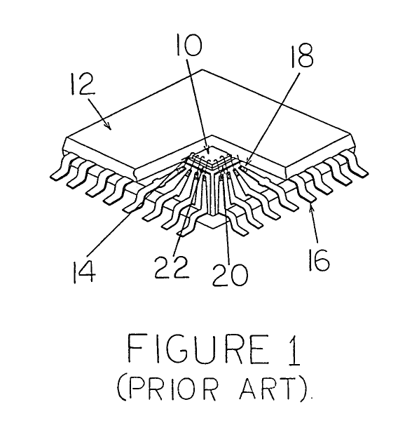

FIGS. 2(a) to (d) depict a variety of integrated circuit capacitor structures of the prior art;

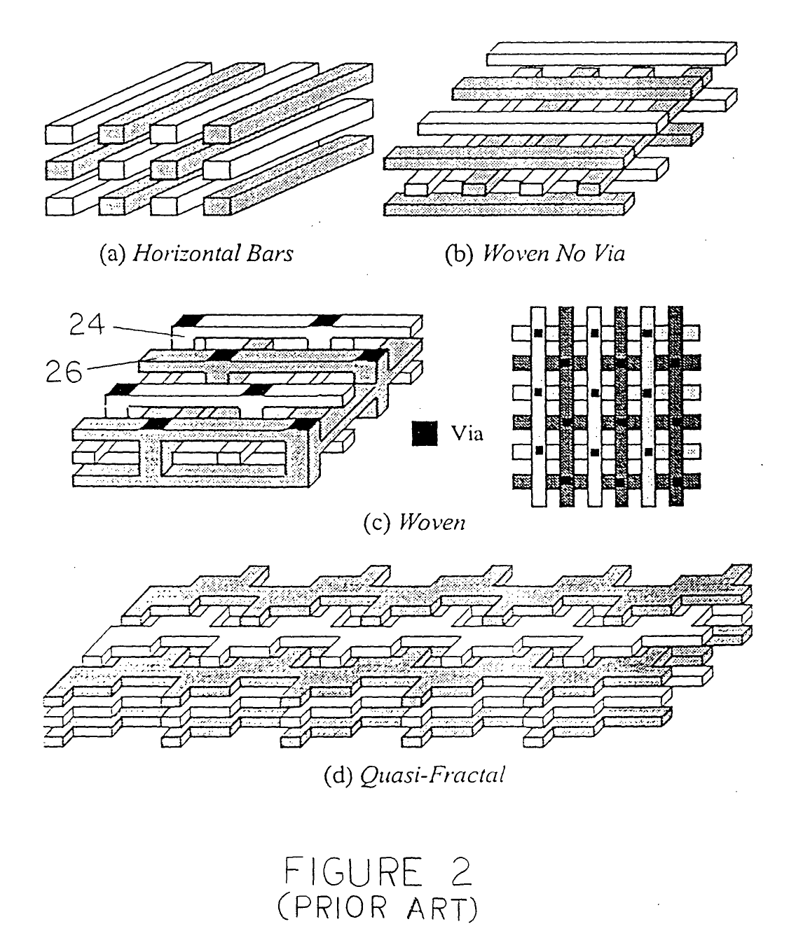

FIGS. 3(a) to (c) depict several capacitor structures and the electrostatic fields associated therewith of the prior art;

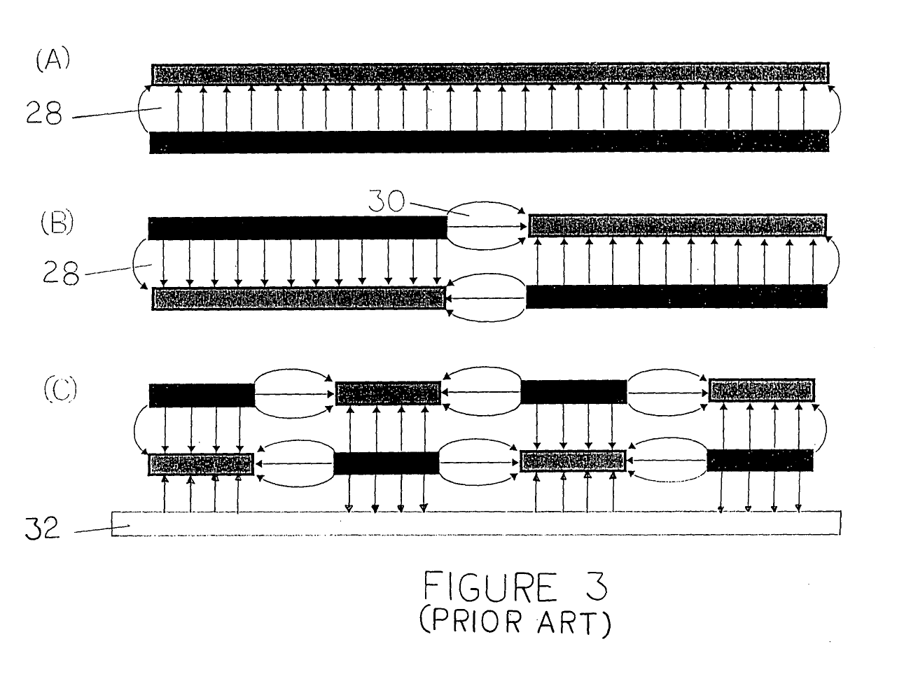

FIG. 4 depicts a preferred embodiment of the present invention;

FIG. 5 depicts a second embodiment of the present invention;

FIG. 6 depicts a third embodiment of the present invention; and

FIG. 7 depicts a fourth embodiment of the present invention.

### DETAILED DESCRIPTION OF THE PREFERRED EMBODIMENT

In essence, the invention contemplates an improved integrated capacitor structure of a single or multi-layer nature, which minimizes the affects of offset inherent in the photolithographic process.

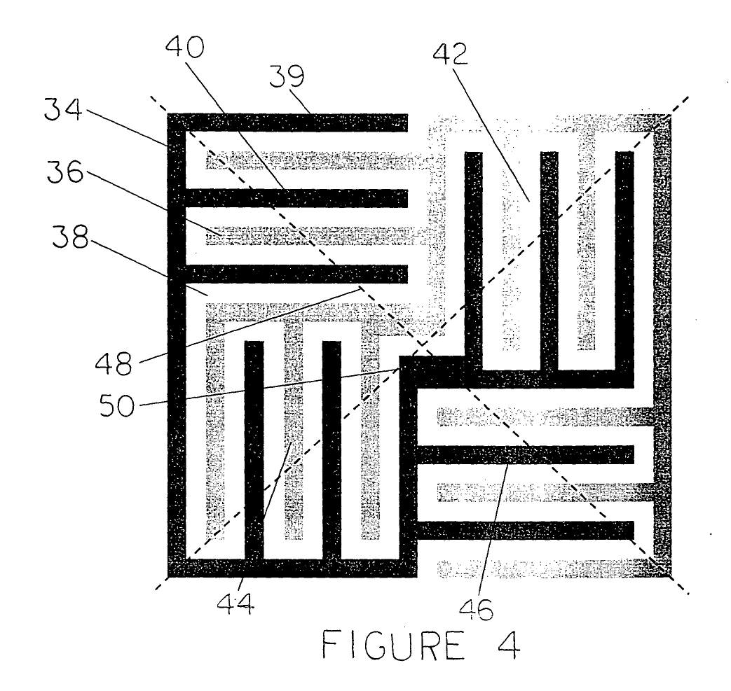

FIG. 4 depicts a preferred embodiment of the present invention. Two conductive components 34, 36 are shown, with one conductive region being generally darker than the other for the purposes of illustration. The components 34, 36 are spaced apart by a predetermined distance 38, with each component being comprised of a plurality of interleaved digital rectangular sub-components 39, as will be more fully described below. The distance 38 is normally determined by the minimum spacing rules set out in the physical design specification for the integrated circuit technology in use. Capacitance is created between the two components 34, 36 due to the lateral flux through the dielectric (not shown) separating them. The total capacitance of the inter-digital structure is made up primarily from the perimeter of the facing edges of the two conductive components 34, 36. As will be appreciated, the two conductive components 34, 36 are conductive electrodes with the two conductive components 34, 36 positioned in a common layer or plane of the integrated circuit die.

The overall capacitor structure of FIG. 4 is made up of four separate regions. Each conductive component 34, 36 is defined by the orientation of the digital sub-components 39 within each respective region. The upper left region 40 has digital sub-components 39 perpendicular to the digital sub-components of upper right region 42. The lower right region 44 has digital sub-components 39 parallel to the digital sub-components 39 of upper left region 46. The lower left region 44 is again perpendicular to the upper left region 40 but parallel to the upper right region 42. The entire structure is symmetrical if mirrored about both diagonal axes 48, 50. In other words, it is identical if rotated 180 degrees. The overall structure also has symmetry in the number of digital sub-components 39 that are oriented in a given direction and the different orientations are arranged in a common centroid fashion about the center of the capacitor. Within each region 40, 42, 44 and 46, the respective digital sub-components 39 of each component 34, 36 are interleaved.

While the preferred embodiment shows four distinct regions 40, 42, 44, 46 to obtain an overall equality in the orientation of the digital sub-components 39, it is understood that this structure could be extended to more regions, given a larger area. Each region would contain digital sub-components 39 which originated from lines extending from the center of the structure, as in the four region case depicted in FIG. 4.

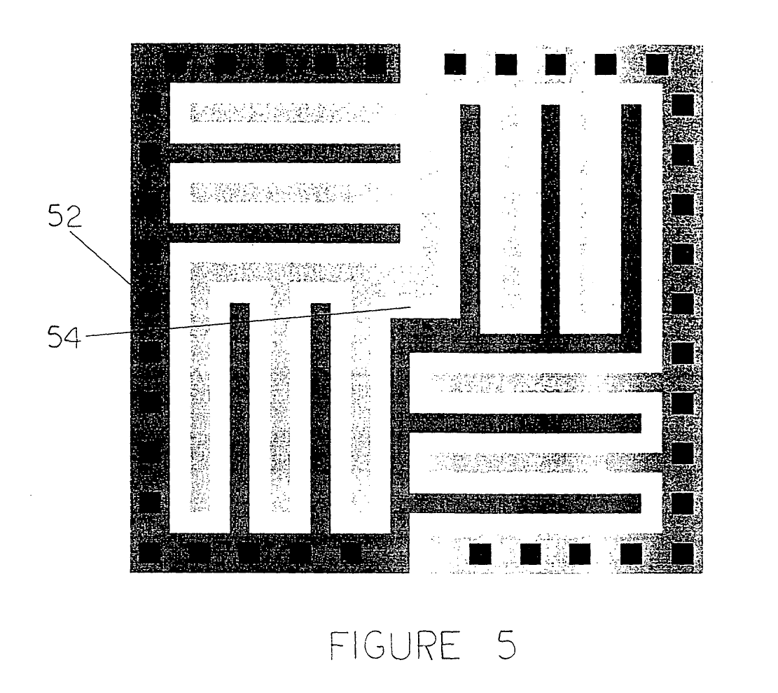

FIG. 5 illustrates a second embodiment of the present invention, whereby two parallel layers (the bottom layer not shown) are present, one on top of another. The bottom layer is identical to the top layer, having two conductive components with their digital sub-components similarly oriented. The respective conductive components in the two layers are connected by vias 52 and separated by a dielectric (not shown). The vias 52 are typical of those defined by the physical design specification in use. As will be understood by those in the art, vias are generally placed so as to minimize the parasitic resistance of the capacitor. In this case, the capacitor is still made up of primarily lateral flux, as the two different conductive regions in each layer do not overlap the unrelated conductive regions in the next layer. As with the single layer structure of

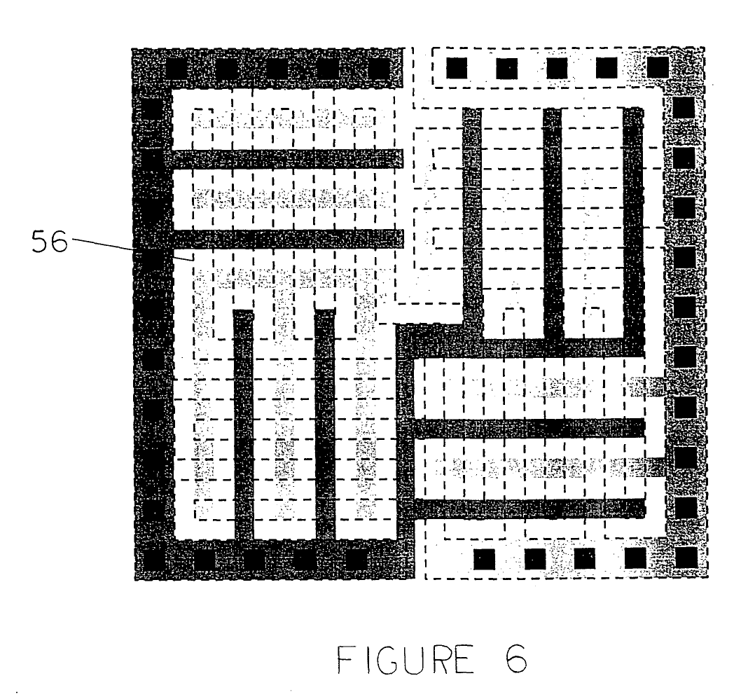

FIG. 5, the multi-layer structure of FIG. 6 is also symmetrical, being arranged in a three (as opposed to two) dimensional common centroid.

While the present embodiment shows the inter-layer connections using vias 52 at the outermost conductors only, other embodiments could have the inter-layer connections created differently. For example, the region at the center of the structure 54 could be used for via connections or the via connections could be made throughout the structure, provided that the digital sub-components 39 are made wide enough to allow for them. This alternate arrangement is meant to be included within the scope of the invention.

FIG. 6 illustrates a third embodiment of the present invention, whereby the bottom layer 56 (outlined with a dashed line) is identical to the bottom layer of the FIG. 5 embodiment, except that the orientation of the capacitor structure in the bottom layer is rotated 90 degrees i.e. the digital sub-components 39 in the bottom layer 56 for each of the four regions described in relation to FIG. 4, are perpendicular to the conductors in the first layer. This arrangement has the effect of increasing the overall capacitance by using vertical flux where the conductive region in one layer coincides with the unrelated conductive region in the next layer. The vertical flux, as well as the lateral flux from the structure in FIG. 4, combines to give an overall higher capacitance. While the higher capacitance density may be desirable, the vertical flux can suffer from more variation over different areas on the chip and from one chip to another, compared to the lateral flux as described in Aparcio, R and Hajimiri, A in “Capacity Limits and Matching Properties of Integrated Capacitors”, IEEE Journal of Solid State Circuits, vol. 37 no. 3, March 2002. As with the structure of FIG. 6, the multi-layer structure of FIG. 6 is also symmetrical, being arranged in centroid in three dimensions.

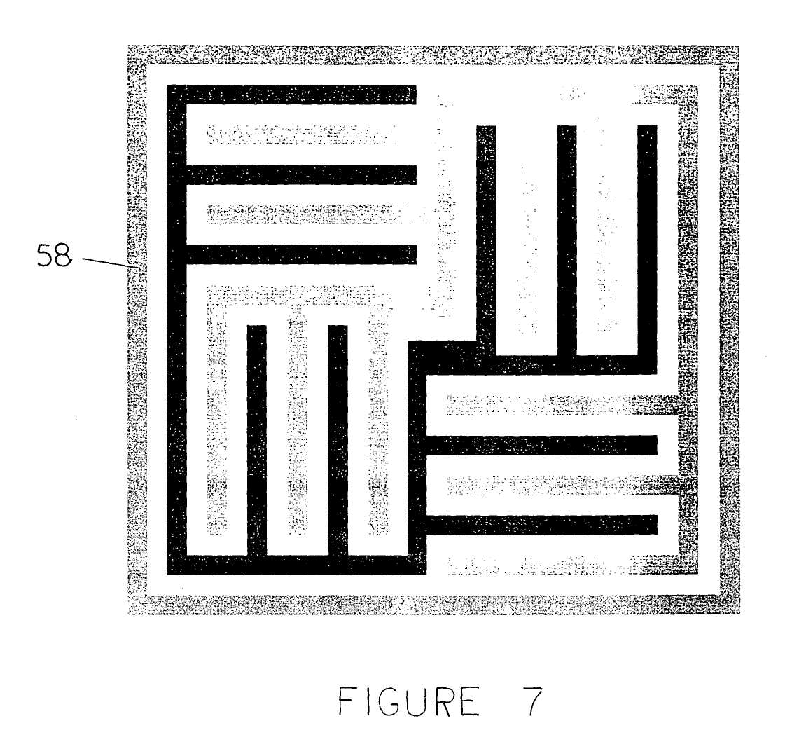

FIG. 7 illustrates the fourth embodiment of the present invention which incorporates a perimeter conductive component 58. This perimeter conductive component 58 surrounds the entire structure, maintaining the same distance from each outer edge. The conductive component 58 serves to minimize the variation in the parasitic capacitances at the edges of the capacitor structure. With the perimeter conductive component 58, the parasitics at the outside edges of the capacitor will not depend on structures that are placed near to the capacitor. As will be appreciated, this outside conductor can be extended to all the layers in which the capacitor structure is present. This perimeter conductive component 58 may be electrically connected to a power signal or ground signal or it may be left as a floating node.

In all the examples described above, the resultant capacitor structure can be used as an array, where the structure described above is used as the unit section of the array. By varying the orientation of the cells in the array a uniform, well-matched capacitor array can be created.

As will be understood by those skilled in the art, the present invention relates to integrated circuits incorporating a unique capacitor structure. The integrated circuit capacitor described herein can be used in combination with other components to form a useful circuit function for either analog or digital chips. It is to be understood by the reader that a variety of other implementations may be devised by skilled persons for substitution and the claimed invention herein is intended to encompass all such alternative implementations, substitutions and equivalents. Persons skilled in the field of integrated circuit design will be readily able to apply the present invention to an appropriate implementation for a given application.

Consequently, it is to be understood that the particular embodiments shown and described herein by way of illustration are not intended to limit the scope of the invention claimed by the inventors/assignee, which is defined by the appended claims.

We claim:

1. An integrated circuit capacitor comprising:
(a) a first conductive component comprising a plurality of digital sub-components; and
(b) a second conductive component comprising a plurality of digital sub-components;
wherein the digital sub-components of said first and second conductive components are interleaved and parallel, with a narrow uniform distance therebetween;
and wherein the orientation of said interleaved digital sub-components is symmetrical about the center of said integrated circuit capacitor.

2. The integrated circuit capacitor of claim 1 wherein said first and second conductive components are oriented about a common plane.

3. The integrated circuit capacitor of claim 2 wherein said first and second conductive components are conductive electrodes.

4. The integrated circuit capacitor of claim 3 wherein said conductive components form at least four distinct regions within said common plane, and wherein the overall structure of said integrated circuit capacitor is a common centroid.

5. The integrated circuit capacitor of claim 4 further comprising at least a second plane parallel to said common plane and having third and fourth conductive components disposed therein, wherein said third and fourth conductive components are identically oriented as said first and second conductive components, and wherein said first conductive component is electrically coupled to said third conductive component and said second conductive component is electrically coupled to said fourth conductive component using a plurality of vias.

6. The integrated circuit capacitor of claim 5 wherein said plurality of vias extend between said common plane and said second plane about the center of said integrated circuit capacitor.

7. The integrated circuit capacitor of claim 4 further comprising at least a second plane parallel to said common plane and having third and fourth conductive components disposed therein, wherein said third and fourth conductive components are oriented in a 90° relationship to said first and second conductive components, and wherein said first conductive component is electrically coupled to said third conductive component and said second conductive component is electrically coupled to said fourth conductive component using a plurality of vias.

8. The integrated circuit capacitor of claim 7 wherein said plurality of vias extend between said common plane and said second plane about the center of said integrated circuit capacitor.

9. The integrated circuit capacitor of claim 3 further comprising a perimeter conductive component extending around said first and second conductive components.

10. The integrated circuit capacitor of claim 9 wherein said perimeter conductive component is electrically coupled to a ground.

11. The integrated circuit capacitor of claim 2 wherein said integrated circuit capacitor is a unit section in a capacitor array formed in said common plane.
